(19) United States
(12) Patent Application Publication
(10) Pub. No.: US 2016/0093476 A1
(43) Pub. Date: Mar. 31, 2016

(54) Substrate Processing Apparatus, Method of Manufacturing Semiconductor Device and Non-Transitory Computer-Readable Recording Medium

(71) Applicant: Hitachi Kokusai Electric Inc., Tokyo (JP)

(72) Inventors: Kazuyuki TOYODA, Toyama (JP); Atsushi UMEKAWA, Toyama (JP); Makoto KAWABATA, Toyama (JP); Koji SHIBATA, Toyama (JP)

(21) Appl. No.: 14/844,784

(22) Filed: Sep. 3, 2015

(30) Foreign Application Priority Data
Sep. 26, 2014 (JP) JP2014-196414

(51) Int. Cl. H01J 37/32; H01L 21/673

(52) U.S. Cl. CPC H01J 37/32449; H01J 37/32458; H01L 21/67313; H01J 2237/332

(57) ABSTRACT

Provided is a technique of uniformly processing a substrate within a short time by supplying a sufficient amount of active species to a surface of the substrate. A substrate processing apparatus includes: a process chamber; a discharge chamber; a plasma source; an exhaust system; a process gas supply system including a temporary storage unit; and a control unit configured to control the plasma source, the exhaust system and the process gas supply system to: intermittently supply a process gas temporarily stored in the temporary storage unit into the discharge chamber; and supply the process gas activated in the discharge chamber from the discharge chamber into the process chamber having an inner pressure lower than an inner pressure of the discharge chamber.

### CROSS REFERENCE TO RELATED APPLICATIONS

This application claims foreign priority under 35 U.S.C. §119(a)-(d) to Application No. JP 2014-196414 filed on Sep. 26, 2014, the entire contents of which are hereby incorporated by reference.

### FIELD OF THE INVENTION

The present invention relates to a substrate processing apparatus, a method of manufacturing a semiconductor device and a non-transitory computer-readable recording medium.

### BACKGROUND

A substrate processing process of forming a film on a substrate using plasma is performed as a process of manufacturing a semiconductor device (device) such as a dynamic random access memory (DRAM).

When substrate processing is performed using a substrate processing apparatus, a film is formed on a substrate by supplying active species of a process gas excited by plasma to the substrate accommodated in a process chamber.

However, in the case of a substrate processing apparatus according to the related art, an inner pressure of a process chamber increases when a plasma-excited process gas is supplied. Thus, since a considerable ratio of active species are exhausted via a peripheral space of a substrate, a sufficient amount of the active species is not supplied to a surface of the substrate and thus the surface of the substrate cannot be efficiently processed.

Also, the active species cannot be supplied into a depth trench in an integrated circuit formed on a surface of the substrate.

### SUMMARY

It is a main object of the present invention to provide a technique of uniformly processing a substrate within a short time by supplying a sufficient amount of active species onto a surface of the substrate.

According to one aspect of the present invention, there is provided a technique including: a process chamber where a substrate is processed; a discharge chamber configured to supply a process gas in activated state into the process chamber; a plasma source configured to activate the process gas in the discharge chamber; an exhaust system configured to exhaust an atmosphere in the process chamber; a process gas supply system including a temporary storage unit configured to temporarily store the process gas, wherein the process gas supply system is configured to supply the process gas into the discharge chamber; and a control unit configured to control the plasma source, the exhaust system and the process gas supply system to: intermittently supply the process gas temporarily stored in the temporary storage unit into the discharge chamber; and supply the process gas activated in the discharge chamber from the discharge chamber into the process chamber having an inner pressure lower than an inner pressure of the discharge chamber.

### BRIEF DESCRIPTION OF THE DRAWINGS

FIG. 1 is a schematic vertical cross-sectional view of a process furnace of a substrate processing apparatus according to an embodiment of the present invention.

FIG. 2 is a schematic configuration diagram of a portion of a process furnace of a substrate processing apparatus according to an embodiment of the present invention, taken along line A-A of FIG. 1.

FIG. 3 is a diagram illustrating a film forming sequence according to an embodiment of the present invention.

FIG. 4 is a graph illustrating a change in an inner pressure of a discharge chamber when NH3 gas is supplied.

FIG. 5 is a schematic plan cross-sectional view of a first modified example of a process furnace of a substrate processing apparatus according to an embodiment of the present invention.

FIG. 6 is a schematic plan cross-sectional view of a second modified example of a process furnace of a substrate processing apparatus according to an embodiment of the present invention.

FIG. 7 is a schematic configuration diagram of a controller of a substrate processing apparatus according to an embodiment of the present invention, in which a control system of the controller is illustrated in a block diagram.

### DETAILED DESCRIPTION

Hereinafter, exemplary embodiments of the present invention will now be described with reference to the accompanying drawings.

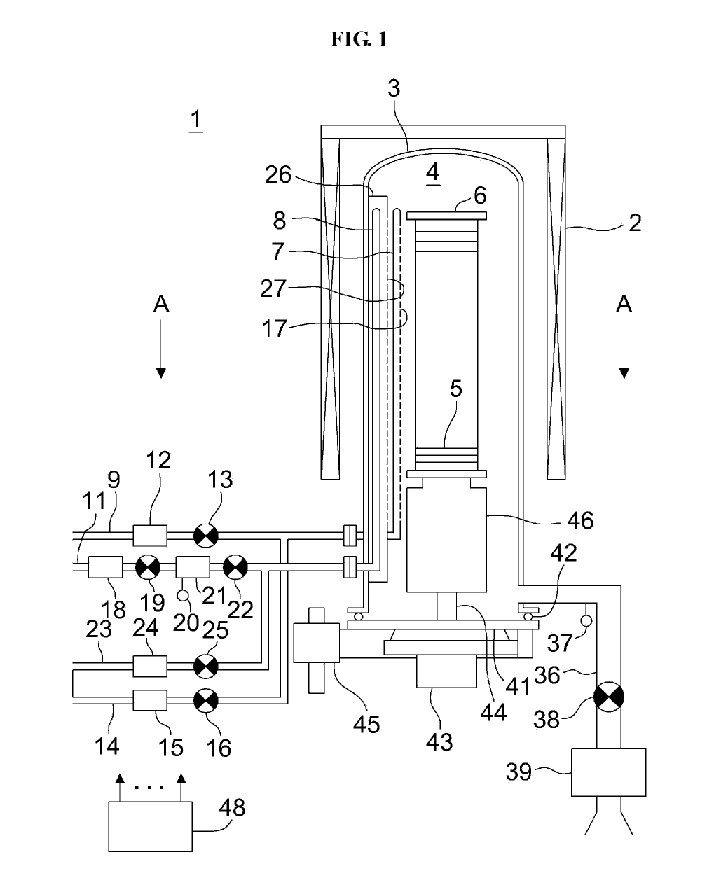

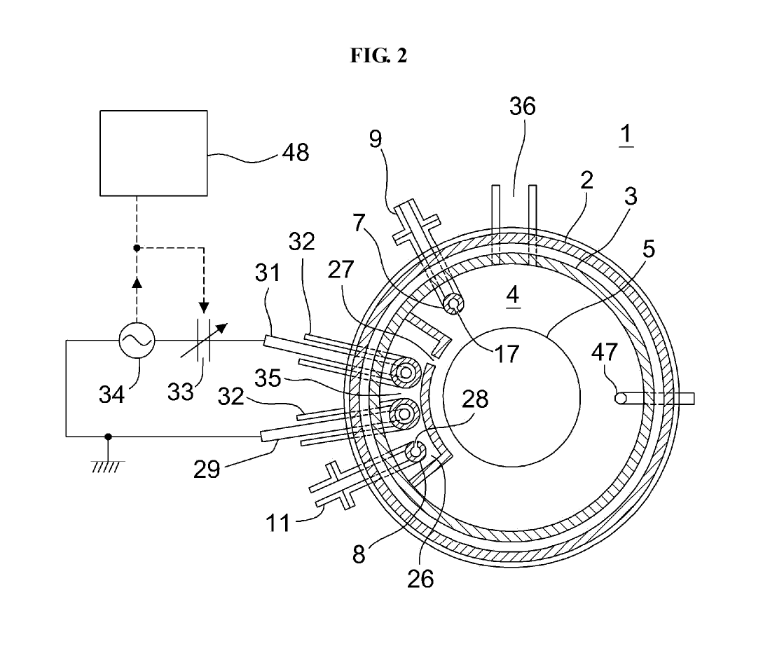

First, a process furnace 1 of a substrate processing apparatus according to an embodiment of the present invention will be described with reference to FIGS. 1 and 2.

The process furnace 1 includes a heater 2 serving as a heating means (heating mechanism). The heater 2 has a cylindrical shape and is vertically installed by being supported by a heater base (not shown) serving as a support plate. The heater 2 may also function as an activating mechanism configured to active a process gas by heat as will be described below.

At an inner side of the heater 2, a reaction tube 3 is installed concentrically with the heater 2 to form a reaction container (process container). The reaction tube 3 is formed of, for example, a heat-resistant material such as quartz (SiO₂) or silicon carbide (SiC), and has a cylindrical shape, the top end of which is closed and the bottom end of which is open. In the reaction tube 3, a process chamber 4 is formed. The process chamber 4 is configured to accommodate wafers (substrates) 5 such that the wafers (substrates) 5 are vertically arranged in a horizontal posture by a boat 6 which will be described below.

In the process chamber 4, a first nozzle 7 and a second nozzle 8 are installed below the reaction tube 3 to pass through side walls of the reaction tube 3. A first gas supply pipe 9 and a second gas supply pipe 11 are connected to the first nozzle 7 and the second nozzle 8, respectively. As described above, in the reaction tube 3, the two nozzles 7 and 8 may be installed to supply a plurality of types of process gases into the process chamber 4. In the present embodiment, the process chamber 4 is configured such that two types of process gases (a source gas and a reactive gas) are supplied thereinto.

At the first gas supply pipe 9, a mass flow controller (MFC) 12 which is a flow rate controller (a flow rate control unit) and a valve 13 which is an opening/closing valve are sequentially installed from an upstream end. Also, a first inert gas supply pipe 14 is connected to the first gas supply pipe 9 at a downstream side of the valve 13. At the first inert gas supply pipe 14, an MFC 15 and a valve 16 are sequentially installed from the upstream end. The first nozzle 7 is connected to a front end portion of the first gas supply pipe 9.

The first nozzle 7 is configured as an L-shaped long nozzle. The first nozzle 7 is installed to move, in an arc-shaped space between inner walls of the reaction tube 3 and the substrates 5, upward from the bottom of the inner walls of the reaction tube 3 in a direction in which the substrates 5 are arranged. A plurality of gas supply holes 17 are formed in a side surface of the first nozzle 7 to supply a gas. The plurality of gas supply holes 17 are open toward the center of the reaction tube 3. The plurality of gas supply holes 17 are formed from the bottom of the reaction tube 3 to the top thereof and each have the same opening area at the same opening pitch.

A first process gas supply system mainly includes the first gas supply pipe 9, the MFC 12, the valve 13 and the first nozzle 7. A first inert gas supply system mainly includes the first inert gas supply pipe 14, the MFC 15 and the valve 16.

At the second gas supply pipe 11, an MFC 18, a first valve 19, a gas tank 21 configured to temporarily store a process gas and a second valve 22 are sequentially installed from the upstream end. At the gas tank 21, a pressure sensor 20 is installed to sense a pressure in the gas tank 21. The first valve 19, the pressure sensor 20, the gas tank 21 and the second valve 22 form a temporary storage unit configured to temporarily store a process gas. Although the pressure sensor 20 and the gas tank 21 are elements of the temporary storage unit in the present embodiment, the temporary storage unit may be configured by at least the first valve 19 and the second valve 22 without the pressure sensor 20 and the gas tank 21. That is, since a process gas may be temporarily stored in a pipe between the first valve 19 and the second valve 22, a portion between the first valve 19 and the second valve 22 may function as the temporary storage unit when the temporary storage unit is configured by the first valve 19 and the second valve 22.

A second inert gas supply pipe 23 is connected to the second gas supply pipe 11 at a downstream side of the second valve 22. At the second inert gas supply pipe 23, an MFC 24 and a valve 25 are sequentially installed from the upstream end. The second nozzle 8 is connected to a front end portion of the second gas supply pipe 11. The second nozzle 8 is installed in a discharge chamber 26 which is a gas dispersion space.

In the arc-shaped space between the inner walls of the reaction tube 3 and the substrates 5, the discharge chamber 26 is installed in a region ranging from the bottom of the inner walls of the reaction tube 3 to the top thereof in the direction in which the substrates 5 are arranged. Gas supply holes 27 are formed in an end portion of a wall of the discharge chamber 26 adjacent to the substrate 5 so as to supply a reactive gas into the process chamber 4. The gas supply holes 27 are open toward the center of the reaction tube 3. The gas supply holes 27 are formed from the bottom of the reaction tube 3 to the top thereof and each have the same opening area at the same opening pitch. Also, wall portions that constitute the discharge chamber 26 include isolation walls that isolate the inside of the process chamber 4 and the inside of the discharge chamber 26.

The second nozzle 8 is configured as an L-shaped long nozzle. The second nozzle 8 is formed on an end portion of the discharge chamber 26 opposite the end portion thereof in which the gas supply holes 27 are formed so as to move from the bottom of the inner walls of the reaction tube 3 to the top of the reaction tube 3, i.e., to move upward in the direction in which the substrates 5 are arranged. Gas supply holes 28 (see FIG. 2) are formed in a side surface of the second nozzle 8 to supply a process gas into the discharge chamber 26. The gas supply holes 28 are open toward the center of the discharge chamber 26. The gas supply holes 28 are formed from the bottom of the reaction tube 3 to the top thereof, similar to the gas supply holes 27 of the discharge chamber 26. The gas supply holes 28 may be set to each have the same opening area and the same opening pitch from the upstream end (bottom) to the downstream end (top) when a differential pressure between the inside of the discharge chamber 26 and the inside of the process chamber 4 is high. When the differential pressure is low, the differential pressure between the inside of the discharge chamber 26 and the inside of the process chamber 4 may be increased by gradually increasing the opening areas of the gas supply holes 28 or gradually decreasing the number of the gas supply holes 28 from the upstream end to the downstream end.

In the present embodiment, the opening areas or pitches of the gas supply holes 28 of the second nozzle 8 from the upstream end to the downstream end are adjusted as described above, so that process gases having different flow velocities may be discharged from the gas supply holes 28 at substantially the same flow rate. The different flow velocities of process gases emitted via the gas supply holes 27 in the discharge chamber 26 may be controlled to be the same by introducing the process gases discharged from the gas supply holes 28 into the discharge chamber 26.

That is, the speed of particles of the process gas emitted into the discharge chamber 26 via the gas supply holes 28 of the second nozzle 8 decreases in the discharge chamber 26 and the process gas is then emitted into the process chamber 4 via the gas supply holes 27 of the discharge chamber 26. The process gas emitted into the discharge chamber 26 via the gas supply holes 28 of the second nozzle 8 is controlled to have a uniform flow rate and velocity when the process gas is emitted into the process chamber 4 via the gas supply holes 27 of the discharge chamber 26.

Also, since the gas tank 21 is installed at the second gas supply pipe 11 to temporarily store a process gas, the process gas may be emitted at once into the discharge chamber 26 at high pressure via the gas supply holes 28.

A second process gas supply system mainly includes the second gas supply pipe 11, the MFC 18, the first valve 19, the gas tank 21, the second valve 22, the second nozzle 8 and the discharge chamber 26. Also, a second inert gas supply system mainly includes the second inert gas supply pipe 23, the MFC 24 and the valve 25.

For example, a silicon source gas, i.e., a gas containing silicon (Si) (a silicon-containing gas) is supplied as a first process gas (a source gas) into the process chamber 4 from the first gas supply pipe 9 via the MFC 12, the valve 13 and the first nozzle 7. For example, dichlorosilane (SiH₂Cl₂, abbreviated as ‘DCS’) gas may be used as the silicon-containing gas.

For example, a nitrogen-containing gas is supplied as a second process gas (a reactive gas) containing, for example, nitrogen (N) into the process chamber 4 from the second gas supply pipe 11 via the MFC 18, the first valve 19, the gas tank 21, the second valve 22, the second nozzle 8 and the discharge chamber 26. For example, ammonia (NH₃) gas may be used as the nitrogen-containing gas.

For example, nitrogen (N₂) gas is supplied into the process chamber 4 from the inert gas supply pipe 14 via the MFC 15, the valve 16, the gas supply pipe 9, the nozzle 7 and the discharge chamber 26, and is supplied into the process chamber 4 from the inert gas supply pipe 23 via the MFC 24, the valve 25, the gas supply pipe 11, the nozzle 8 and the discharge chamber 26.

Also, when various gases are supplied from, for example, these gas supply pipes, the silicon-containing gas supply system (a silane-based gas supply system) is configured by the first process gas supply system. Also, a nitrogen-containing gas supply system is configured by the second process gas supply system. Also, a process gas supply system is configured by the first process gas supply system and the second process gas supply system. When the first process gas is also referred to as a source gas, the first process gas supply system may be also referred to as a source gas supply system. When the second process gas is also referred to as a reactive gas, the second process gas supply system may be also referred to as a reactive gas supply system. In the present disclosure, when the term “process gas” is used, it should be understood to mean only the first process gas (source gas), only the second process gas (reactive gas), or both of them.

As illustrated in FIG. 2, in the discharge chamber 26, a first rod-shaped electrode 29 and a second rod-shaped electrode 31 which are first and second electrodes each having a slender and long structure are installed from the bottom of the reaction tube 3 to the top of the reaction tube 3 in the direction in which the substrates 5 are stacked. The first and second rod-shaped electrodes 29 and 31 are installed in parallel with the second nozzle 8. The first and second rod-shaped electrodes 29 and 31 are protected by being covered with electrode protection pipes 32 (which are configured to protect electrodes) from top to bottom. One of the first rod-shaped electrode 29 and the second rod-shaped electrode 31 is connected to a high-frequency power source 34 via an impedance matching device 33, and the other is connected to the earth having a reference electric potential.

Thus, plasma is generated in a plasma generation region 35 between the first rod-shaped electrode 29 and the second rod-shaped electrode 31. A plasma source serving as a plasma generator (a plasma generation unit) mainly includes the first rod-shaped electrode 29, the second rod-shaped electrode 31, the electrode protection pipes 32, the impedance matching device 33 and the high-frequency power source 34. Also, the plasma source functions as an activating mechanism configured to activate a process gas to a plasma state as will be described below, and includes a capacitively-coupled plasma source that is installed in the discharge chamber 26 and that includes the first and second rod-shaped electrodes 29 and 31.

The electrode protection pipes 32 are configured to be inserted into the discharge chamber 26 in a state in which the first and second rod-shaped electrodes 29 and 31 are isolated from an atmosphere in the discharge chamber 26. When an atmosphere in the electrode protection pipes 32 is substantially the same as that in the air (atmosphere), the first rod-shaped electrode 29 and the second rod-shaped electrode 31 inserted into the electrode protection pipes 32 are oxidized by heat generated from the heater 2. Thus, in the electrode protection pipes 32, an inert-gas purging mechanism is installed to fill or purge the electrode protection pipes 32 with an inert gas such as nitrogen so that the concentration of oxygen in the electrode protection pipes 32 may be deceased enough to prevent the first rod-shaped electrode 29 or the second rod-shaped electrode 31 from being oxidized.

An exhaust pipe 36 is installed in the reaction tube 3 to exhaust an atmosphere in the process chamber 4. A vacuum pump 39 serving as a vacuum exhaust device is connected to the exhaust pipe 36, and a pressure sensor 37 serving as a pressure detector (a pressure detection unit) for detecting an inner pressure of the process chamber 4 and an auto pressure controller (APC) valve 38 serving as a pressure adjustor (a pressure adjust unit) are disposed between the vacuum pump 39 and the exhaust pipe 36. The vacuum pump 39 is configured to vacuum-exhaust the inside of the process chamber 4 to a desired pressure (degree of vacuum). The APC valve 38 is an opening/closing valve configured to perform or suspend vacuum-exhaust in the process chamber 4 by opening/closing the APC valve 38 and to adjust the inner pressure of the process chamber 4 by controlling the degree of openness of the APC valve 38. An exhaust system mainly includes the exhaust pipe 36, the pressure sensor 37 and the APC valve 38. The exhaust system may further include the vacuum pump 39.

Below the reaction tube 3, a seal cap 41 is installed as a furnace port lid for air-tightly closing a lower end aperture of the reaction tube 3. The seal cap 41 is configured to come in contact with a lower end of the reaction tube 3 from below in a vertical direction. The seal cap 41 is formed of, for example, a metal such as stainless steel and has a disc shape. An O-ring 42 serving as a seal member that comes in contact with the lower end of the reaction tube 3 is installed on an upper surface of the seal cap 41. A rotation mechanism 43 that rotates the boat 6 is installed at a side of the seal cap 41 opposite the process chamber 4. A rotation shaft 44 of the rotation mechanism 43 is connected to the boat 6 while passing through the seal cap 41, and configured to rotate the substrate 5 by rotating the boat 6. The seal cap 41 is configured to be vertically moved by a boat elevator 45 that is a lifting mechanism vertically installed outside the reaction tube 3, and to load the boat 6 into or unload the boat 6 from the process chamber 4 using the boat elevator 45.

The boat 6 serving as a substrate support mechanism is formed of, for example, a heat-resistant material such as quartz or silicon carbide, and configured to support a plurality of substrates 5 to be arranged in a horizontal posture and a concentric fashion, in a multistage manner. An insulating member 46 formed of, for example, a heat-resistant material such as quartz or silicon carbide is installed below the boat 6. The insulating member 46 is configured to suppress heat generated from the heater 2 from being transferred to the seal cap 41. Also, the insulating member 46 may include a plurality of insulting plates formed of a heat-resistant material such as quartz or silicon carbide, and an insulating plate holder configured to support the plurality of insulating plates in a horizontal posture and a multistage manner.

A temperature sensor 47 serving as a temperature detector is installed in the reaction tube 3. The temperature in the process chamber 4 may be controlled to have a desired temperature distribution by controlling an amount of electric current to be supplied to the heater 2 based on temperature information detected by the temperature sensor 47. The temperature sensor 47 has an L shape similar to the first and second nozzles 7 and 8, and is installed along an inner wall of the reaction tube 3.

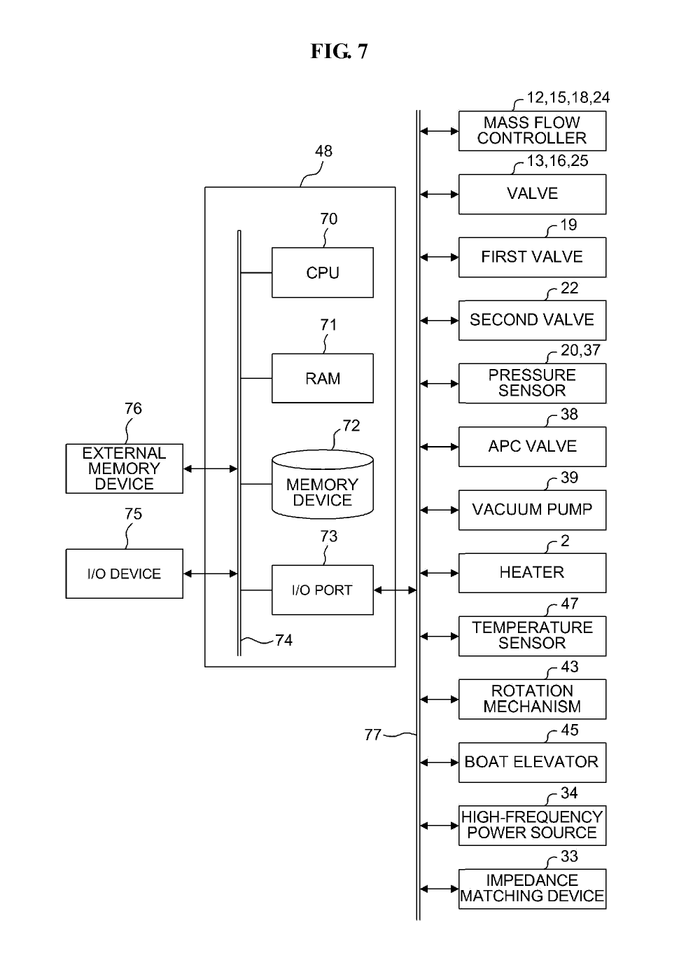

Referring to FIG. 7, a controller 48 which is a control unit (control means) is configured as a computer that includes a central processing unit (CPU) 70, a random access memory (RAM) 71, a memory device 72 and an input/output (I/O) port 73. The RAM 71, the memory device 72 and the I/O port 73 are configured to exchange data with the CPU 70 via an internal bus 74. An I/O device 75 configured as a touch panel or the like is connected to the controller 48.

The memory device 72 is configured, for example, as a flash memory, a hard disk drive (HDD), etc. In the memory device 72, a control program for controlling an operation of a substrate processing apparatus, a process recipe including the order or conditions of substrate processing which will be described below, or the like is stored to be readable. The process recipe is a combination of sequences (steps) of a substrate processing process which will be described below to obtain a desired result when the sequences (steps) are performed by the controller 48, and acts as a program. Hereinafter, the process recipe, the control program, etc. will be referred to together simply as a ‘program.’ When the term ‘program’ is used in the present disclosure, it may be understood as including only a process recipe, only a control program, or both of the process recipe and the control program. The RAM 71 is configured as a memory area (work area) in which a program or data read by the CPU 70 is temporarily stored.

The I/O port 73 is connected to the MFCs 12, 15, 18 and 24, the valves 13, 16 and 25, the first valve 19, the second valve 22, the pressure sensors 20 and 37, the APC valve 38, the vacuum pump 39, the heater 2, the temperature sensor 47, the rotation mechanism 43, the boat elevator 45, the high-frequency power source 34, the impedance matching device 33, etc. via a bus 77.

The CPU 70 is configured to read and execute the control program from the memory device 72 and to read the process recipe from the memory device 72 according to a manipulation command or the like received via the I/O device 75. The CPU 70 is configured to, based on the read process recipe, control the flow rates of various gases via the MFCs 12, 15, 18 and 24; control opening/closing of the valves 13, 16 and 25, control opening/closing of the first valve 19 and the second valve 22 based on the pressure sensor 20; control the degree of pressure by opening/closing the APC valve 38 and based on the pressure sensor 37; control temperature using the heater 2, based on the temperature sensor 47; control driving/suspending of the vacuum pump 39; control the rotation speed of the rotation mechanism 43; control upward/downward movement of the boat elevator 45; control power supply from the high-frequency power source 34; and control impedance using the impedance matching device 33.

The controller 48 is not limited to a dedicated computer and may be configured as a general-purpose computer. For example, the controller 48 according to the present embodiment may be configured by providing an external memory device 76 storing a program as described above, e.g., a magnetic disk (e.g., a magnetic tape, a flexible disk, a hard disk, etc.), an optical disc (e.g., a compact disc (CD), a digital versatile disc (DVD), etc.), a magneto-optical (MO) disc, or a semiconductor memory (e.g., a Universal Serial Bus (USB) memory, a memory card, etc.) and then installing the program in a general-purpose computer using the external memory device 76. However, the means for supplying a program to a computer are not limited to using the external memory device 76. For example, a program may be supplied to a computer using a communication means, e.g., the Internet or an exclusive line, without using the external memory device 76. The memory device 72 or the external memory device 76 may be configured as a non-transitory computer-readable recording medium. Hereinafter, the memory device 72 and the external memory device 76 may also be referred to together simply as a ‘recording medium.’ When the term ‘recording medium’ is used in the present disclosure, it may be understood as only the memory device 72, only the external memory device 76, or both of the memory device 72 and the external memory device 76.

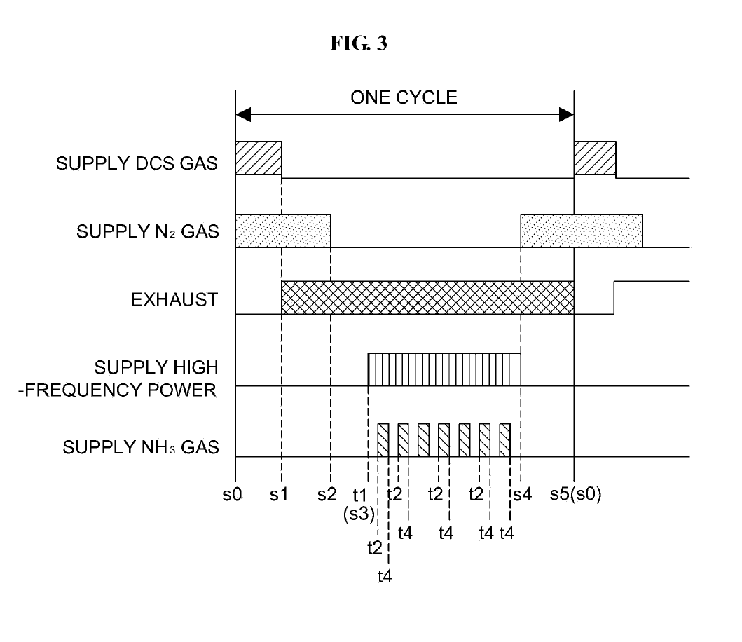

An example of a sequence of forming a nitride film on the substrate 5 will now be described as a process of manufacturing a semiconductor device (device) using the process furnace 1 with reference to FIG. 3. In the following description, operations of various elements of the substrate processing apparatus are controlled by the controller 48.

In the present embodiment, a case in which a silicon nitride film (SiN film) is formed on the substrate 5 using DCS gas (a silicon-containing gas) as a first process gas (source gas) and NH₃ gas (a nitrogen-containing gas) as a second process gas (reactive gas) will be described below. Also, in the present embodiment, the silicon-containing gas supply system is configured by the first process gas supply system, and the nitrogen-containing gas supply system is configured by the second process gas supply system.

When the boat 6 is loaded (charged) with a plurality of substrates 5, the boat 6 supporting the plurality of substrates 5 is lifted by the boat elevator 45 and loaded into the process chamber 4 (boat loading) as illustrated in FIG. 1. The lower end of the reaction tube 3 is air-tightly closed by the seal cap 41 via the O-ring 42 in a state in which the boat 6 is loaded into the process chamber 4.

Next, the vacuum pump 39 vacuum-exhausts the inside of the process chamber 4 to a desired pressure (degree of vacuum). In this case, the pressure in the process chamber 4 is measured by the pressure sensor 37 and the APC valve 38 is feedback-controlled based on the measured pressure (pressure control). The inside of the process chamber 4 is heated to a desired temperature by the heater 2. In this case, an amount of electric current supplied to the heater 2 is feedback-controlled based on temperature information detected by the temperature sensor 47, so that the inside of the process chamber 4 may have a desired temperature distribution (temperature control). Then, the substrates 5 are rotated by rotating the boat 6 by the rotation mechanism 43 (substrate rotation). Thereafter, seven steps which will be described below are sequentially performed.

In step 01, DCS gas is supplied into the process chamber 4 to form a silicon-containing layer on the substrate 5. After the inside of the process chamber 4 has a desired pressure and temperature, the valve 13 of the first gas supply pipe 9 is opened, the flow rate of the DCS gas flowing through the first gas supply pipe 9 is controlled by the MFC 12, and the flow rate-controlled DCS gas is supplied into the process chamber 4 to a point of time s1 via the gas supply holes 17 of the first nozzle 7, in a state in which the degree of openness of the APC valve 38 is 0% (the APC valve 38 is fully closed) and exhausting of the inside of the process chamber 4 is stopped.

The valve 25 is opened to supply an inert gas such as N₂ into the second inert gas supply pipe 23, in parallel with the supply of the DCS gas. The flow rate of the N₂ gas flowing through the second inert gas supply pipe 23 is controlled by the MFC 24, and the flow rate-controlled N₂ is supplied into the discharge chamber 26 via the gas supply holes 28 of the second nozzle 8 and then supplied into the process chamber 4 via the gas supply holes 27. When the N₂ gas is supplied into the process chamber 4 via the gas supply holes 27, the DCS gas may be prevented from flowing into the discharge chamber 26, and the DCS gas and the N₂ gas may be exhausted from the exhaust pipe 36.

In this case, since a silicon-containing layer needs to be formed on a surface of the substrate 5 within a short time, the DCS gas may be supplied in a state in which exhausting of the inside of the process chamber 4 is stopped. That is, since the APC valve 38 is fully closed, the inner pressure of the process chamber 4 continuously increases after a point of time s0 at which the supply of the DCS gas starts. The state in which the inner pressure of the process chamber 4 continuously increases is maintained for about 1 to 3 seconds. A range of an increase in the pressure in the process chamber 4 is preferably set from 200 Pa to 2,000 Pa during which the pressure in the process chamber 4 continuously increases. In this case, the supply flow rate of the DCS gas is set to be, for example, in a range of 1 sccm to 2,000 sccm, and preferably, a range of 10 sccm to 1,000 sccm. Also, in this case, the temperature of the heater 2 is set such that chemical vapor deposition (CVD) occurs on the substrate 5 in the process chamber 4, i.e., such that the temperature of the substrate 5 is, for example, in a range of 300° C. to 600° C. When the temperature of the substrate 5 is less than 300° C., the DCS gas is difficult to be adsorbed onto the substrate 5. When the temperature of the substrate 5 exceeds 650° C., a gas-phase reaction becomes stronger and thus film thickness uniformity is likely to be degraded. Thus, the temperature of the substrate 5 is preferably set to be, for example, in a range of 300° C. to 600° C.

Under the conditions described above, the DCS gas is supplied to the substrate 5 to form a silicon layer (Si layer) as a silicon-containing layer to a thickness of less than one atomic layer to several atomic layers on an integrated circuit on the surface of the substrate 5. The silicon-containing layer may be an adsorption layer of the DCS gas. Examples of the silicon layer include a continuous layer formed of silicon (Si), a discontinuous layer formed of silicon (Si) and a thin film formed by overlapping the continuous layer and the discontinuous layer. Examples of the adsorption layer of the DCS gas include an adsorption layer including continuous gas molecules of the DCS gas but also an adsorption layer including discontinuous gas molecules of the DCS gas. When the thickness of a silicon-containing layer formed on the substrate 5 exceeds a thickness of several atomic layers, nitrification which will be described below does not affect the entire silicon-containing layer. A minimum value of a thickness of the silicon-containing layer that may be formed on the substrate 5 is less than one atomic layer. Thus, the silicon-containing layer is preferably formed to a thickness of less than one atomic layer to several atomic layers. Silicon (Si) is deposited on the substrate 5 to form a silicon-containing layer under conditions in which DCS gas is self-decomposed. DCS gas is chemically adsorbed onto the substrate 5 to form an adsorption layer of the DCS gas under conditions in which the DCS gas is not self-decomposed. A film-forming rate may be higher when the silicon-containing layer is formed on the substrate 5 than when the adsorption layer of the DCS gas is formed on the substrate 5.

In step 02, the inside of the process chamber 4 is purged. After the silicon-containing layer is formed on the substrate 5, the valve 16 of the first inert gas supply pipe 14 is opened at the point of time S1 to supply N₂ gas into the process chamber 4 via the gas supply holes 17 of the first nozzle 7 while the valve 13 is closed and the supply of the DCS gas is stopped. In this case, the N₂ gas is continuously supplied into the process chamber 4 via the second nozzle 8 in a state in which the valve 25 of the second inert gas supply pipe 23 is open. Also, the APC valve 38 of the exhaust pipe 36 is opened and the inside of the process chamber 4 is exhausted via the vacuum pump 39. Thus, the inside of the process chamber 4 is vacuum-exhausted while the inside of the process chamber 4 is purged with the N₂ gas, and thus the DCS gas (that did not react or that has contributed to the formation of the silicon-containing layer) remaining in the process chamber 4 is removed from the process chamber 4. A time period during which the N₂ gas is supplied via the first nozzle 7 and the second nozzle 8 is preferably set to be in a range of 1 to 5 seconds.

Not only an inorganic source, such as tetrachlorosilane (SiCl₄, abbreviated as ‘TCS’) gas, hexachlorodisilane (Si₂Cl₆, abbreviated as ‘HCDS’) gas, monosilane (SiH₄ gas), etc., but also an organic source which is an aminosilane-based gas, such as tetrakis(dimethylamino)silane (Si[N(CH₃)₂]₄, abbreviated as ‘4DMAS’) gas, tris(dimethylamino)silane (Si[N(CH₃)₂]₃H, abbreviated as ‘3DMAS’) gas, bis(diethylamino)silane (Si[N(C₂H₅)₂]₂H₂, abbreviated as ‘2DEAS’) gas, bis(tertiary-butylamino)silane (SiH₂[NH(C₄H₉)]₂, abbreviated as ‘BTBAS’) gas, etc., may be used as the silicon-containing gas, in addition to the DCS gas. As the inert gas, a rare gas, such as Ar gas, He gas, Ne gas, Xe gas, etc., may be used in addition to N₂ gas.

In step 03, vacuum-sucking is performed in the process chamber 4. After the N₂ gas is supplied into the process chamber 4 via the first nozzle 7 and the second nozzle 8 for a predetermined time (from the point of time s1 to a point of time s2), at the point of time s2, the valve 16 of the first inert gas supply pipe 14 and the valve 25 of the second inert gas supply pipe 23 are closed, supply of various gases into the process chamber 4 is stopped, and the APC valve 38 is fully opened. Although the supply of the gases into the process chamber 4 is stopped, vacuum-exhausting is continuously performed by the vacuum pump 39 to reduce the inside pressure of the process chamber 4 to a low pressure. In this case, the inside pressure of the process chamber 4 is reduced to be less than the inside pressure of the discharge chamber 26 at a point of time when generation of active species of NH₃ gas begins, i.e., a pressure satisfying the Paschen's law which will be described below. For example, the inside pressure of the process chamber 4 is reduced to a high-vacuum state which is 10 Pa or less and is preferably in a range of 1 Pa or less.

In steps 04 through 06, active species of NH₃ gas are supplied into the process chamber 4 and the silicon-containing layer is modified to a silicon nitride layer. Steps 05 and 06 (the point of time t2 to a point of time t4) are repeatedly performed a predetermined number of times, and active species of NH₃ gas are supplied in the form of pulse into the process chamber 4 a plurality of times (flash flow).

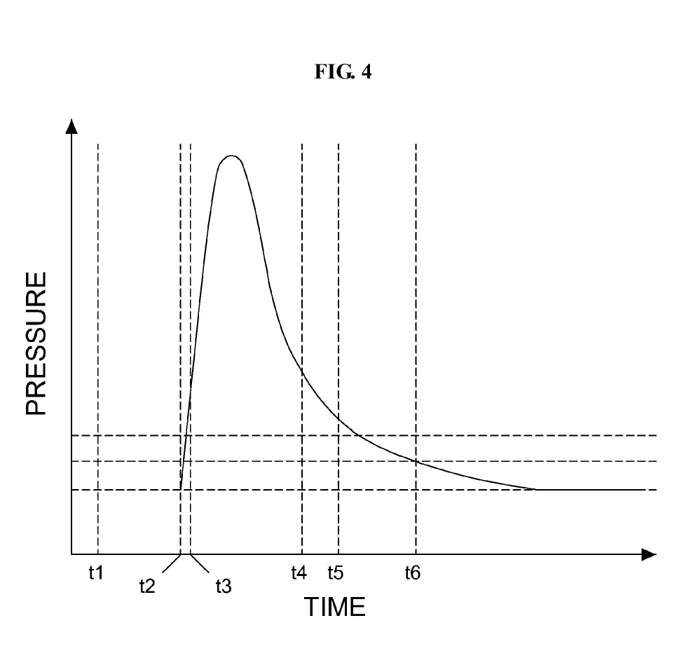

FIG. 4 is a graph illustrating a change in an inner pressure of the discharge chamber 26 when NH₃ gas is supplied, in which a vertical axis denotes a pressure and a horizontal axis denotes time. A process of supplying NH₃ gas into the discharge chamber 26 in step 04 will be described with reference to FIGS. 3 and 4 below.

In step 04, high-frequency power is supplied to the first and second rod-shaped electrodes 29 and 31. After the inside of the process chamber 4 is continuously vacuum-exhausted for a predetermined time to reduce the inner pressure of the process chamber 4, high-frequency power is supplied to the first rod-shaped electrode 29 and the second rod-shaped electrode 31 from the high-frequency power source 34 via the impedance matching device 33 at a point of time t1 (the point of time s3).

In step 05, NH₃ gas is supplied into the discharge chamber 26. After the high-frequency power is supplied, the second valve 22 is opened at a time t2 to immediately supply high-pressure NH₃ gas, which is filled beforehand in the gas tank 21, into the discharge chamber 26, thereby sharply increasing the inner pressure of the discharge chamber 26. In this case, the valve 19 is closed.

Here, the NH₃ gas may be filled into the gas tank 21 at an arbitrary timing in one of steps 01 through 04 or filled into the gas tank 21 before step 01. The inside of the gas tank 21 is filled with the NH₃ gas by opening the valve 19 in a state in which the valve 22 is closed. When the pressure sensor 20 senses that the inside pressure of the gas tank 21 is equal to a predetermined pressure which will be described below, the valve 19 is closed and the filling of the gas tank 21 with the NH₃ gas is completed.

After supply of the NH₃ gas into the discharge chamber 26 begins, at a point of time t3, the inside pressure of the discharge chamber 26 becomes equal to a pressure satisfying the Paschen's law. When the inside pressure of the discharge chamber 26 satisfies the Paschen's law, a discharge occurs in the discharge chamber 26 to generate plasma in the plasma generation region 35. When the plasma is generated, active species of the NH₃ gas is generated.

The inside pressure of the process chamber 4 is low at a point of time (e.g., the point of time t3) when the inside pressure of the discharge chamber 26 sharply increases and generation of the active species of the NH₃ gas begins. Thus, the active species of the NH₃ gas of high density generated in the plasma generation region 35 are immediately supplied into the process chamber 4 via the gas supply holes 27. In this case, since a pressure between the substrates 5 stacked together is lower than the inside pressure of the discharge chamber 26, the active species may be sufficiently supplied between the stacked substrates 5.

Thus, the silicon-containing layer formed on the surface of the substrate 5 is nitridated by the active species of the NH₃ gas and modified into a silicon nitride layer (SiN layer) containing silicon and nitrogen. Also, since an inner pressure of a deep groove in the integrated circuit on the surface of the substrate 5 is also lower than the inside pressure of the discharge chamber 26, the active species may be also sufficiently supplied into the deep groove and thus a silicon nitride layer having high coverage may be formed. Also, in the process of supplying the NH₃ gas (the point of time s3 to the point of time s4), vacuum-exhausting is continuously performed using the vacuum pump 39, and non-reacted active species, active species remaining after the nitridation of the silicon-containing layer, or byproducts are exhausted via the exhaust pipe 36.

Although the inner pressure of the discharge chamber 26 is set to continuously increase even after plasma is generated and plasma is generated to change a state thereof according to a change in the inner pressure of the discharge chamber 26, the inner pressure of the discharge chamber 26 decreases due to a decrease in the amount of the NH₃ gas in the gas tank 21, i.e., a decrease in the flow rate of the NH₃ gas supplied into the discharge chamber 26.

The second valve 22 is closed at the point of time t4 and the supply of the NH₃ gas into the discharge chamber 26 is stopped. Even after the supply of the NH₃ gas into the discharge chamber 26 is stopped, active species of the NH₃ gas are continuously generated in the plasma generation region 35 until the plasma disappears at a point of time t6.

In step 06, the inside of the gas tank 21 is filled with NH₃ gas. After the supply of the NH₃ gas is stopped, at a point of time t5, the first valve 19 of the second gas supply pipe 11 is opened and NH₃ gas, the flow rate of which is controlled by the MFC 18, flows into the gas tank 21. In this case, since the second valve 22 is closed, the inner pressure of the gas tank 21 increases due to the NH₃ gas flowing thereinto. The inner pressure of the gas tank 21 is measured by the pressure sensor 20, and the MFC 18 and the first valve 19 are feedback-controlled such that the inner pressure of the gas tank 21 is equal to a desired pressure, e.g., a pressure that is in a range of 0.05 MPa to 0.1 MPa. When the inner pressure of the gas tank 21 increases to a predetermined pressure, the first valve 19 is closed.

Also, the filling of the inside of the gas tank 21 with the NH₃ gas may begin simultaneously with stopping of the supply of the NH₃ gas into the discharge chamber 26. That is, the first valve 19 may be opened simultaneously with closing of the second valve 22. In other words, the point of time t4 and the point of time t5 may overlap with each other. When the inside of the gas tank 21 is filled with the NH₃ gas simultaneously with stopping of the supply of the NH₃ gas into the discharge chamber 26, a time required to fill the inside of the gas tank 21 with the NH₃ gas may be reduced and thus flash flow intervals may decrease.

The amount of the NH₃ gas filled in the gas tank 21 is equal to or greater than an inner pressure of the discharge chamber 26 that satisfies the Paschen's law when the NH₃ gas filled in the gas tank 21 is supplied into the discharge chamber 26. That is, the amount of the NH₃ gas filled in the gas tank 21 is equal to or greater than an inner pressure of the discharge chamber 26 that causes a discharge to occur in the discharge chamber 26 so as to generate plasma in the plasma generation region 35. That is, the predetermined pressure means an inner pressure of the gas tank 21 when the gas tank 21 is filled with the NH₃ gas, the amount of which is equal to or greater than an inner pressure of the discharge chamber 26 satisfying the Paschen's law when the NH₃ gas filled in the gas tank 21 is supplied into the discharge chamber 26.

After the inside of the gas tank 21 is filled with the NH₃ gas at the predetermined pressure, step 05 (the point of time t2) is performed again to reopen the second valve 22 and supply NH₃ gas into the discharge chamber 26.

A high-quality nitride film may be formed on the surface of the substrate 5 by supplying active species of NH₃ gas in the form of pulse into the process chamber 4 a plurality of times by repeatedly performing steps 05 and 06 described above (the point of time t2 to the point of time t4) a predetermined number of times, e.g., seven times.

Also, since the filling of the NH₃ gas into the gas tank 21 per time and the supply of the NH₃ gas into the discharge chamber 26 from the gas tank 21 per time are both completed within short times, the NH₃ gas is supplied from the gas tank 21 to the discharge chamber 26 in a flash flow (flash time-division supply) such that the supply of the NH₃ gas and stopping of the supply of the NH₃ gas are intermittently and repeatedly performed.

In the present embodiment, a sharp change in the inner pressure of the discharge chamber 26 results in a sharp change in the impedance of plasma. Thus, an impedance matching condition at the high-frequency power source 34 is set by fixing a matching constant of the impedance matching device 33 to a desired state and setting impedance control not to be automatically performed. In detail, a discharge pressure is set such that a maximum inner pressure of the discharge chamber 26 or a pressure that is slightly lower than the maximum pressure is equal to a pressure that satisfies the Paschen's law, and the impedance matching condition at the high-frequency power source 34 is set.

As the nitrogen-containing gas, not only a gas obtained by exciting NH₃ gas to a plasma state but also a hydronitrogen-based gas such as diazene (N₂H₂) gas, hydrazine (N₂H₄) gas, N₃H₈ gas or a gas obtained by exciting N₂ gas to a plasma state may be used. Alternatively, a result of exciting a gas, which is obtained by diluting one of these gases with a rare gas such as Ar gas, He gas, Ne gas, Xe gas, etc., to a plasma state may be used.

In step 07, the inside of the process chamber 4 is purged after the flash flow of the NH₃ gas (the point of time s4 to the point of time s5). After the flash flow of the NH₃ gas is performed a predetermined number of times, supply of high-frequency power from the high-frequency power source 34 is stopped at the point of time s4, the valves 16 and 25 are opened, and N₂ gas is supplied via the gas supply holes 17 of the first nozzle 7 and the gas supply holes 28 of the second nozzle 8. A duration for which the N₂ gas is supplied via the first nozzle 7 and the second nozzle 8 is preferably set to be in a range of 0 to 1 second.

While the inside of the process chamber 4 is purged, vacuum-exhausting is continuously performed using the vacuum pump 39, and NH₃ gas (that did not react or that has contributed to nitridation) or byproducts remaining in the discharge chamber 26 and the process chamber 4 are purged by the supplied N₂ gas and removed from the inside of the process chamber 4.

A thin film containing silicon and nitrogen, i.e., a silicon nitride film (SiN film), may be formed on the substrate 5 to a desired thickness by performing one cycle including steps 01 through 07 described above (the point of time s0 to the point of time s5) at least once. The above cycle is preferably performed a plurality of times. Step 07 may be skipped. When step 07 is skipped, a time needed to perform step 07 so as to form a film may be saved, thereby improving the throughput.

When a film-forming process of forming a silicon nitride film to a desired thickness is completed, the inside of the process chamber 4 is purged with an inert gas such as N₂ by supplying the inert gas into the process chamber 4 and exhausting the inside of the process chamber 4 (gas purging). Then, an atmosphere in the process chamber 4 is replaced with the inert gas (inert gas replacement) and the inner pressure of the process chamber 4 is restored to normal pressure (atmospheric pressure recovery).

Then, when the seal cap 41 is moved downward by the boat elevator 45, the lower end of the reaction tube 3 is opened and the processed substrate 5 is unloaded to the outside of the reaction tube 3 from the lower end of the reaction tube 3 while being supported by the boat 6 (boat unloading). Thereafter, the processed substrate 5 is unloaded from the boat 6 (discharging).

According to the present embodiment, one or more of the following effects can be achieved.

(1) A large amount of active species of a process gas having high density may be supplied into a process chamber in one cycle by supplying the process gas into a discharge chamber in a flash flow, thereby increasing the productivity.

(2) Active species of the process gas may be supplied even between substrates or into a deep groove in an integrated circuit on a substrate by setting the inner pressure of the process chamber to be lower than the inner pressure of the discharge chamber when the process gas is supplied into the discharge chamber, thereby increasing coverage.

(3) Flash flow intervals may be reduced by closing a valve at a downstream side of a gas tank, stopping the supply of the process gas into the discharge chamber, and starting filling of the process gas into the gas tank, before the process gas supplied into the discharge chamber is completely supplied into a process chamber, thereby reducing a time needed to form a film. Also, the number of flash flows may be increased. Therefore, the productivity may be improved.

(4) High-speed plasma corresponding to the flash flow of the process gas may be repeatedly generated and lost by setting an impedance matching condition of a high-frequency power source such that a maximum inner pressure of the discharge chamber or a pressure that is slightly lower than the maximum inner pressure satisfies the Paschen's law.

Also, although a case in which an SiN film is formed using a silicon-containing gas and a nitrogen-containing gas has been described in the present embodiment, the present invention is not limited thereto.

For example, the present invention is applicable to a case in which an aluminum nitride film (AlN film) is formed using an aluminum-containing gas and a nitrogen-containing gas, a case in which a titanium nitride film (TiN film) is formed using a titanium-containing gas and a nitrogen-containing gas, a case in which a boron nitride film (BN film) is formed using a boron-containing gas and a nitrogen-containing gas, etc. Also, the present invention is applicable to a case in which a silicon oxide film (SiO film) is formed using a silicon-containing gas and an oxygen-containing gas, a case in which an aluminum oxide film (AlO film) is formed using an aluminum-containing gas and an oxygen-containing gas, a case in which a titanium oxide film (TiO film) is formed using a titanium-containing gas and an oxygen-containing gas, a case in which a silicon carbide film (SiC film) is formed using a silicon-containing gas and a carbon-containing gas, etc.

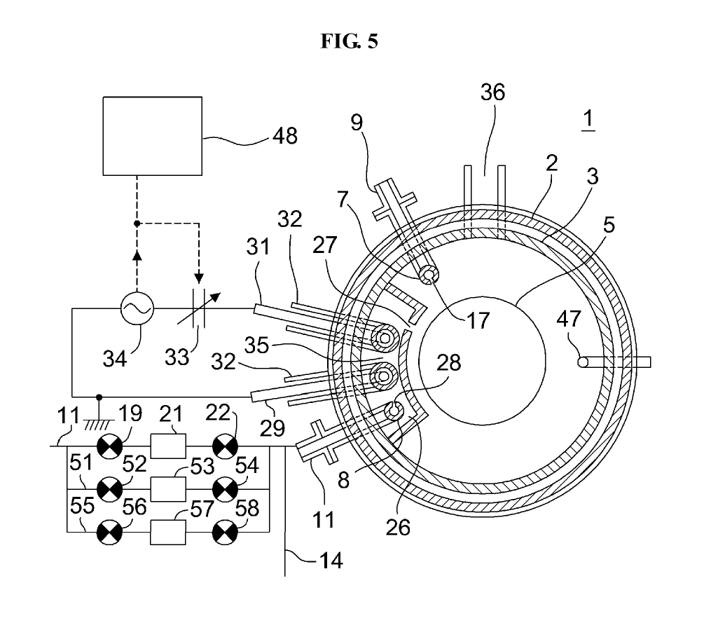

FIG. 5 illustrates a first modified example of the process furnace 1 according to the present invention.

In the first modified example, a first branch pipe 51 is connected in parallel to a second gas supply pipe 11 at an upstream side of a first valve 19 and a downstream side of a second valve 22 of the second gas supply pipe 11. A third valve 52, a gas tank 53 and a fourth valve 54 are sequentially installed at the first branch pipe 51 from an upstream end.

A second branch pipe 55 is connected in parallel to the first branch pipe 51 at an upstream side of the third valve 52 and a downstream side of the fourth valve 54 of the first branch pipe 51. A fifth valve 56, a gas tank 57 and a sixth valve 58 are sequentially installed at the second branch pipe 55 from the upstream end.

Thus, the second gas supply pipe 11, the first branch pipe 51 and the second branch pipe 55 are connected in parallel to one another, and a gas tank 21, the gas tank 53 and the gas tank 57 are connected in parallel to one another.

In the first modified example, after NH₃ gas is supplied from the gas tank 21 into a discharge chamber 26, the NH₃ gas may be supplied into the discharge chamber 26 from the gas tank 53 and the gas tank 57 while the inside of the gas tank 21 is filled with new NH₃ gas. Thus, a standby time required to fill and supply NH₃ gas may be reduced and thus a more fine flash flow may be performed, thereby improving a processing capability of the process furnace.

Also, a large amount of NH₃ gas may be supplied into the discharge chamber 26 by simultaneously opening a plurality of gas tanks.

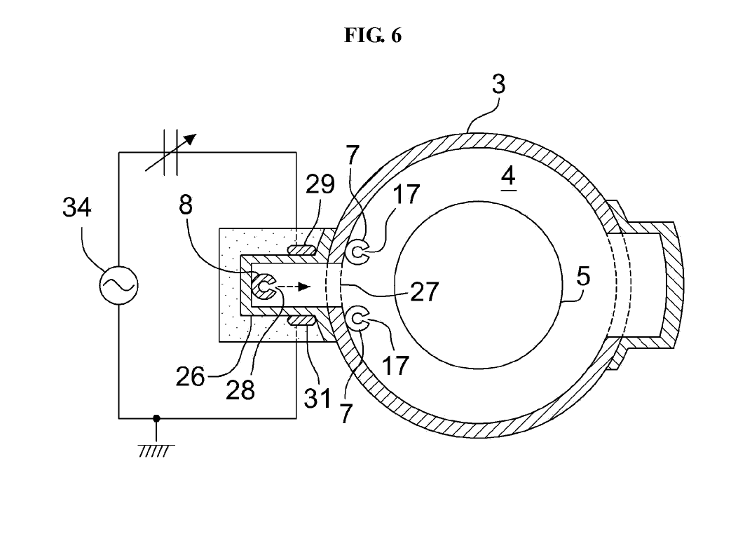

FIG. 6 illustrates a second modified example of the process furnace 1 according to the present invention.

Cases in which the discharge chamber 26 is installed along an inner wall of the reaction tube 3 have been described in the present embodiment and the first modified example. However, even if a discharge chamber 26 is installed to protrude toward the outside of a reaction tube 3 as in the second modified example of FIG. 6, effects that are substantially the same as those of an embodiment of the present invention and the first modified example may be obtained.

According to the present invention, a substrate may be uniformly processed within a short time by supplying a sufficient amount of active species to a surface of the substrate.

### Exemplary Embodiments of the Present Invention

Hereinafter, exemplary embodiments according to the present invention are supplementarily noted.

### Supplementary Note 1

According to an aspect of the present invention, there is provided a substrate processing apparatus including:

a process chamber where a substrate is processed; a discharge chamber configured to supply a process gas in activated state into the process chamber; a plasma source configured to activate the process gas in the discharge chamber; an exhaust system configured to exhaust an atmosphere in the process chamber; a process gas supply system including a temporary storage unit configured to temporarily store the process gas, wherein the process gas supply system is configured to supply the process gas into the discharge chamber; and a control unit configured to control the plasma source, the exhaust system and the process gas supply system to: intermittently supply the process gas temporarily stored in the temporary storage unit into the discharge chamber; and supply the process gas activated in the discharge chamber from the discharge chamber into the process chamber having an inner pressure lower than an inner pressure of the discharge chamber.

### Supplementary Note 2

In the substrate processing apparatus of Supplementary note 1, preferably, the temporary storage unit includes a first valve, a gas tank and a second valve along a flow direction of the process gas.

### Supplementary Note 3

In the substrate processing apparatus of any one of Supplementary notes 1 and 2, preferably, the discharge chamber is installed on an inner wall of the process chamber, and the discharge chamber includes an isolation wall having a plurality of gas supply ports, and the isolation wall isolating the discharge chamber from the process chamber.

### Supplementary Note 4

In the substrate processing apparatus of any one of Supplementary notes 1 through 3, preferably, the plasma source includes a capacitively coupled plasma source and is installed in the discharge chamber.

### Supplementary Note 5

In the substrate processing apparatus of any one of Supplementary notes 1 through 4, preferably, the control unit is further configured to control the plasma source and the process gas supply system to apply power to the plasma source before the process gas is introduced into the discharge chamber.

### Supplementary Note 6

In the substrate processing apparatus of Supplementary note 5, preferably, the control unit is further configured to control the plasma source, the exhaust system and the process gas supply system to introduce the process gas into the discharge chamber after lowering the inner pressure of the process chamber.

### Supplementary Note 7

In the substrate processing apparatus of Supplementary note 6, preferably, the control unit is further configured to control the plasma source, the exhaust system and the process gas supply system to plasmatize the process gas by introducing the process gas temporarily stored in the temporary storage unit into the discharge chamber to increase the inner pressure of the discharge chamber.

### Supplementary Note 8

In the substrate processing apparatus of Supplementary note 7, preferably, the control unit is further configured to control the plasma source, the exhaust system and the process gas supply system to increase the inner pressure of the discharge chamber until the inner pressure of the discharge chamber satisfies Paschen's law.

### Supplementary Note 9

In the substrate processing apparatus of any one of Supplementary notes 1 through 8, preferably, the control unit is further configured to control the process gas supply system to store the process gas in the temporary storage unit until the inner pressure of the temporary storage unit reaches a predetermined value.

### Supplementary Note 10

In the substrate processing apparatus of Supplementary note 9, preferably, the predetermined value is equivalent to an inner pressure of the temporary storage unit charged with the process gas by an amount of the process gas charged in the discharge chamber when the inner pressure of the discharge chamber satisfies Paschen's law.

### Supplementary Note 11

In the substrate processing apparatus of any one of Supplementary notes 1 through 10, preferably, the control unit is further configured to control the plasma source, the exhaust system and the process gas supply system to intermittently supply the process gas into the discharge chamber while power is applied to the plasma source.

### Supplementary Note 12

In the substrate processing apparatus of any one of Supplementary notes 1 through 11, preferably, the plasma source includes an impedance matching device installed in a line configured to supply a high frequency power by a high frequency power supply, and a matching constant of the impedance matching device is set (or fixed) such that plasma is generated after the inner pressure of the discharge chamber reaches a discharge pressure.

### Supplementary Note 13

In the substrate processing apparatus of Supplementary note 12, preferably, the control unit is further configured to control the plasma source, the exhaust system and the process gas supply system to stop an impedance control by the impedance matching device after generating plasma in the discharge chamber.

### Supplementary Note 14

According to another aspect of the present invention, there is provided a method of manufacturing a semiconductor device or a substrate processing method including: (a) intermittently supplying a process gas from a temporary storage unit configured to temporarily store the process gas into a discharge chamber disposed in a process chamber and activating the process gas; and (b) supplying the process gas activated in the discharge chamber into the process chamber having an inner pressure lower than an inner pressure of the discharge chamber.

### Supplementary Note 15

According to still another aspect of the present invention, there is provided a program or a non-transitory computer-readable recording medium storing a program causing a computer to perform: (a) intermittently supplying a process gas from a temporary storage unit configured to temporarily store the process gas into a discharge chamber disposed in a process chamber and activating the process gas; and (b) supplying the process gas activated in the discharge chamber into the process chamber having an inner pressure lower than an inner pressure of the discharge chamber.

What is claimed is:

1. A substrate processing apparatus comprising:
a process chamber where a substrate is processed;
a discharge chamber configured to supply a process gas in activated state into the process chamber;
a plasma source configured to activate the process gas in the discharge chamber;
an exhaust system configured to exhaust an atmosphere in the process chamber;
a process gas supply system including a temporary storage unit configured to temporarily store the process gas, wherein the process gas supply system is configured to supply the process gas into the discharge chamber; and
a control unit configured to control the plasma source, the exhaust system and the process gas supply system to: intermittently supply the process gas temporarily stored in the temporary storage unit into the discharge chamber; and supply the process gas activated in the discharge chamber from the discharge chamber into the process chamber having an inner pressure lower than an inner pressure of the discharge chamber.

2. The substrate processing apparatus of claim 1, wherein the temporary storage unit comprises a first valve, a gas tank and a second valve along a flow direction of the process gas.

3. The substrate processing apparatus of claim 1, wherein the discharge chamber is installed on an inner wall of the process chamber, the discharge chamber comprising an isolation wall having a plurality of gas supply ports, the isolation wall isolating the discharge chamber from the process chamber.

4. The substrate processing apparatus of claim 1, wherein the plasma source comprises a capacitively coupled plasma source and is installed in the discharge chamber.

5. The substrate processing apparatus of claim 1, wherein the control unit is further configured to control the plasma source and the process gas supply system to apply power to the plasma source before the process gas is introduced into the discharge chamber.

6. The substrate processing apparatus of claim 5, wherein the control unit is further configured to control the plasma source, the exhaust system and the process gas supply system to introduce the process gas into the discharge chamber after lowering the inner pressure of the process chamber.

7. The substrate processing apparatus of claim 6, wherein the control unit is further configured to control the plasma source, the exhaust system and the process gas supply system to plasmatize the process gas by introducing the process gas temporarily stored in the temporary storage unit into the discharge chamber to increase the inner pressure of the discharge chamber.

8. The substrate processing apparatus of claim 7, wherein the control unit is further configured to control the plasma source, the exhaust system and the process gas supply system to increase the inner pressure of the discharge chamber until the inner pressure of the discharge chamber satisfies Paschen's law.

9. The substrate processing apparatus of claim 1, wherein the control unit is further configured to control the process gas supply system to store the process gas in the temporary storage unit until the inner pressure of the temporary storage unit reaches a predetermined value.

10. The substrate processing apparatus of claim 9, wherein the predetermined value is equivalent to an inner pressure of the temporary storage unit charged with the process gas by an amount of the process gas charged in the discharge chamber when the inner pressure of the discharge chamber satisfies Paschen's law.

11. The substrate processing apparatus of claim 1, wherein the control unit is further configured to control the plasma source, the exhaust system and the process gas supply system to intermittently supply the process gas into the discharge chamber while power is applied to the plasma source.

12. The substrate processing apparatus of claim 1, wherein the plasma source comprises an impedance matching device installed in a line configured to supply a high frequency power by a high frequency power supply, wherein a matching constant of the impedance matching device is set such that plasma is generated after the inner pressure of the discharge chamber reaches a discharge pressure.

13. The substrate processing apparatus of claim 11, wherein the control unit is further configured to control the plasma source, the exhaust system and the process gas supply system to stop an impedance control by the impedance matching device after generating plasma in the discharge chamber.

14. A method of manufacturing a semiconductor device, comprising:
(a) intermittently supplying a process gas from a temporary storage unit configured to temporarily store the process gas into a discharge chamber disposed in a process chamber and activating the process gas; and
(b) supplying the process gas activated in the discharge chamber into the process chamber having an inner pressure lower than an inner pressure of the discharge chamber.

15. A non-transitory computer-readable recording medium storing a program that causes a computer to perform:
(a) intermittently supplying a process gas from a temporary storage unit configured to temporarily store the process gas into a discharge chamber disposed in a process chamber and activating the process gas; and
(b) supplying the process gas activated in the discharge chamber into the process chamber having an inner pressure lower than an inner pressure of the discharge chamber.
